(19) United States
(12) Patent Application Publication
(10) Pub. No.: US 2004/0177788 A1
(43) Pub. Date: Sep. 16, 2004

(54) Interference pigments having a mass tone

(76) Inventors: Norbert Rick, Darmstadt (DE); Lilia Heider, Winchester (GB); Manuela Loch, Klein-Gerau (DE); Nicole Schupp, Gross-Bieberau (DE); Ralf Anselmann, Ramsen (DE)

Correspondence Address: MILLEN, WHITE, ZELANO & BRANIGAN, P.C., 2200 CLARENDON BLVD., SUITE 1400, ARLINGTON, VA, 22201, US

(21) Appl. No.: 10/796,187

(22) Filed: Mar. 10, 2004

(30) Foreign Application Priority Data
Mar. 10, 2003 (DE) 10310736.3

(51) Int. Cl. C23C 16/00; B05D 7/00

(52) U.S. Cl. 106/415; 106/417; 106/418; 427/248.1; 427/212

(57) ABSTRACT

Interference pigments having a mass tone based on multicoated flake-form substrates, which have on the substrate:

(A) a colorless coating having a refractive index of n>1.8 and a layer thickness of 20-250 nm,

(B) a colorless coating having a refractive index of n≦1.8 and a layer thickness of 10-100 nm,

(C) a colorless coating having a refractive index of n>1.8 and a layer thickness of 20-250 nm,

(D) an absorbent layer having a layer thickness of 1-100 nm, and optionally

(E) an outer protective layer,

are described. Also described is the use thereof in paints, coatings, printing inks, plastics, ceramic materials, glasses, for laser marking, in cosmetic formulations and for the preparation of pigment compositions and dry preparations.

The present invention relates to interference pigments having a mass tone based on multicoated flake-form substrates.

Lustre or effect pigments are employed in many areas of industry, in particular in the area of automotive finishes, decorative coatings, in plastics, in paints, in printing inks and in cosmetic formulations.

Lustre pigments based on transparent flake-form substrates which do not have a “hard” metallic lustre are the subject-matter of WO 93/12182. Mica flakes are coated with a high-refractive-index metal-oxide layer, such as, for example, TiO₂, and a non-selectively absorbent layer. These pigments exhibit a certain interference color, depending on the thickness of the TiO₂ layer, in plan view, which becomes weaker as the viewing angle becomes more oblique and finally flops to gray or black. The interference color does not change, but a drop in color saturation is observed.

JP 1992/93206 claims lustre pigments based on glass flakes or mica particles which are coated with an opaque metal layer and alternating SiO₂ and TiO₂ layers.

EP 0 753 545 B1 discloses goniochromatic lustre pigments based on multicoated, high-refractive-index, non-metallic, flake-form substrates which are at least partially transparent to visible light and have at least one layer package comprising a colorless low-refractive-index coating and a reflective, selectively or non-selectively absorbent coating.

The multilayered pigments known from the prior art are in some cases built up from layer materials which are not or only slightly transparent to light and can therefore only be combined with absorption pigments to a very limited extent in the application. The interference color of these pigments is, in addition, very highly dependent on the viewing angle, which is undesired in the majority of applications. Furthermore, these pigments are in some cases very difficult to prepare or reproduce.

An object of the present invention is to provide colored pigments having high tinting strength which have no goniochromaticity, have advantageous applicational properties and/or at the same time can be prepared in a simple manner.

Upon further study of the specification and appended claims, further objects and advantages of this invention will become apparent to those skilled in the art.

Surprisingly, colored pigments based on multicoated, flake-form substrates have now been found which have a certain arrangement of optically functional layers and a thin outer absorbent layer, preferably a metal-oxide layer, through which particular color effects are achieved. An absorption layer on an interference-layer system is generated on the substrate or a substrate mixture. This layer exhibits an interference color at the specular angle and in addition a color which is composed of the interference color and the absorption color of the absorbent layer outside the specular angle. This combination of absorption and interference gives rise to a final colored interference pigment having high lustre and extraordinary color effects.

Effect pigments having colored pigment particles on the outer layer are disclosed, for example, in German Patents 23 13 332 and 33 34 596 (see also U.S. Pat. Nos. 3,951,679 and 4,545,821). The pigments described therein are based on flake-form substrates which are coated with a metal-oxide layer and are subsequently coated with Berlin Blue. However, the pigments from the prior art do not have multiple interference layers. The colored multilayered pigments according to the invention are distinguished over the pigments from the prior art, for example, by their intense body color and high tinting strength, which is defined by the absorption of the oxide system of the outer layer in combination with an interference system consisting of three layers. The pigments according to the invention are furthermore distinguished, for example, by high hiding power, high color purity of the interference color and very high brightness and, in contrast to the goniochromatic pigments from the prior art, such as, for example, EP 0 753 545 B1, preferably have no angle dependence of the interference color.

The invention thus includes interference pigments having a mass tone based on multicoated flake-form substrates, characterized in that they comprise, on the substrate, successively:

(A) a colorless coating having a refractive index of n>1.8 and a layer thickness of 20-250 nm,

(B) a colorless coating having a refractive index of n≦1.8 and a layer thickness of 10-100 nm,

(C) a colorless coating having a refractive index of n>1.8 and a layer thickness of 20-250 nm,

(D) an absorbent layer having a layer thickness of 1-100 nm, and optionally

(E) an outer protective layer.

The invention furthermore relates to the use of the interference pigments according to the invention in paints, coatings, printing inks, plastics, ceramic materials, glasses and for laser marking. Owing to the high tinting strength, the interference pigments according to the invention are particularly suitable for decorative cosmetics. The pigments according to the invention are furthermore also suitable for the preparation of pigment compositions and for the preparation of dry preparations, such as, for example, granules, chips, pellets, briquettes, etc. The dry preparations are particularly suitable for use in printing inks and surface coatings.

Suitable base substrates for the colored pigments according to the invention include transparent flake-form substrates, i.e., platelet-shaped substrates. Preferred substrates are phyllosilicates. Particularly suitable are natural and/or synthetic mica, talc, kaolin, flake-form iron oxides or aluminum oxides, glass flakes, SiO₂ flakes, TiO₂ flakes, graphite flakes, synthetic support-free flakes, BiOCl or other comparable materials. It is also possible to employ mixtures of different substrates or mixtures of identical substrates with different particle sizes. The substrates can be mixed with one another in any ratio. When mixtures are used, preference is given to the use of from 10:1 to 1:10 mixtures by weight, in particular 1:1 mixtures. Particular preference is given to substrate mixtures consisting of mica flakes having different particle sizes, in particular mixtures of N mica (10-60 μm) and F mica (<25 μm).

The size of the base substrates is not crucial per se and can be matched to the particular application. In general, the flake-form substrates can have a thickness of between 0.05 and 5 μm, in particular between 0.1 and 4.5 μm. The size in the other two directions is usually between 1 and 250 μm, preferably between 2 and 200 μm, and in particular between 5 and 60 μm. The above-stated thickness of the individual layers on the base substrate is particularly preferred for the optical properties of the pigment. Layer (B), in particular, has a significant effect on the color properties. Layer (B) should be comparatively thin compared with layers (A) and (C). The ratio of the layer thickness (A) or (C) to (B) is preferably from 2:1 to 5:1. At layer thicknesses (B) of less than 100 nm, the dependence of the hue angle on the viewing angle drops in such a way that only the interference color of the pigment according to the invention can be seen, i.e. no angle-dependent color change between a number of intense interference colors is observed. The absorption layer (D) increases the intensity of this interference color.

For a pigment having high tinting strength, the thickness of the individual layers are preferably set precisely with respect to one another.

The interference pigments according to the invention have alternately a high-refractive-index layer (A) or (C) and a low-refractive-index layer (B). The high-refractive-index layers (A) and (C) have a refractive index of n>1.8, preferably of n>2.0.

Layers (A) and (C) preferably consist of TiO₂, ZrO₂, SnO₂, ZnO, BiOCl or mixtures or combinations thereof. Layers (A) and (C) may be identical or different. Layers (A) and (C) are particularly preferably colorless layers, in particular TiO₂ layers. The TiO₂ here can be in the rutile or anatase modification, preferably in the rutile modification.

The thicknesses of layers (A) and (C) are from 20 to 250 nm, preferably from 20 to 200 nm and in particular from 25 to 180 nm.

Suitable colorless, low-refractive-index materials for coating (B) are preferably metal oxides or the corresponding oxide hydrates, such as, for example, SiO₂, Al₂O₃, AlO(OH), B₂O₃, MgF₂, MgSiO₃ or a mixture of the said metal oxides. Layer (B) preferably consists of SiO₂, MgF₂ or Al₂O₃, or mixtures thereof.

It is advantageous for the optical properties of the pigments according to the invention for layer (B) to be very thin. The thickness of layer (B) is from 10 to 100 nm, preferably from 10 to 90 nm and in particular from 20 to 80 nm.

Layer (D) is a thin layer having layer thicknesses of from 1 to 100 nm, preferably from 1 to 50 nm, in particular from 5 to 20 nm. Layer (D) preferably comprises colored oxides, in particular metal oxides, including mixed oxides, sulfides, tellurides, selenides, lanthanides, actinides and/or mixtures thereof.

Layer (D) particularly preferably consists of metal oxides, such as, for example, Fe₂O₃, Fe₃O₄, Cr₂O₃, Ce₂O₃, molybdenum oxides, CoO, Co₃O₄, VO₂, V₂O₃, NiO, V₂O₅, CuO, Cu₂O, Ag₂O, CeO₂, MnO₂, Mn₂O₃, Mn2O5, titanium oxynitrides, as well as titanium nitride, MoS₂, WS₂ or mixtures or combinations thereof.

Layer (D) preferably contains in particular, of Fe₂O₃ or Fe₃O₄.

The coating of the substrates with a high-refractive-index layer (A), a low-refractive-index layer (B), a further colorless high-refractive-index layer (C) and an absorbent layer (D) results in the formation of colored pigments whose color, lustre and hiding power can be varied within broad limits.

Particularly preferred colored pigments have the following layer sequences:

substrate+TiO₂ (A)+SiO₂ (B)+TiO₂ (C)+Fe₂O₃ (D)

substrate+TiO₂ (A)+SiO₂ (B)+TiO₂ (C)+Fe₃O₄ (D)

substrate+TiO₂ (A)+SiO₂ (B)+TiO₂ (C)+Cr₂O₃ (D)

substrate+TiO₂ (A)+SiO₂ (B)+TiO₂ (C)+Ce₂O₃ (D)

substrate+TiO₂ (A)+SiO₂ (B)+TiO₂ (C)+V₂O₅ (D)

substrate+TiO₂ (A)+SiO₂ (B)+TiO₂ (C)+MnO₂ (D)

substrate+TiO₂ (A)+SiO₂ (B)+TiO₂ (C)+CoO (D)

substrate+TiO₂ (A)+SiO₂ (B)+TiO₂ (C)+Ag₂O (D)

substrate+TiO₂ (A)+Al₂O₃ (B)+TiO₂ (C)+Fe₂O₃ (D)

substrate+TiO₂ (A)+Al₂O₃ (B)+TiO₂ (C)+Fe₃O₄ (D)

substrate+TiO₂ (A)+Al₂O₃ (B)+TiO₂ (C)+Cr₂O₃ (D)

substrate+TiO₂ (A)+Al₂O₃ (B)+TiO₂ (C)+Ce₂O₃ (D)

substrate+TiO₂ (A)+Al₂O₃ (B)+TiO₂ (C)+V₂O₅ D)

substrate+TiO₂ (A)+Al₂O₃ (B)+TiO₂ (C)+MnO₂ D)

substrate+TiO₂ (A)+Al₂O₃ (B)+TiO₂ (C)+CoO (D)

substrate+TiO₂ (A)+Al₂O₃ (B)+TiO₂ (C)+Ag₂O (D)

substrate+TiO₂ (A)+B₂O₃ (B)+TiO₂ (C)+Fe₂O₃ (D)

substrate+TiO₂ (A)+B₂O₃ (B)+TiO₂ (C)+Fe₃O₄ (D)

substrate+TiO₂ (A)+B₂O₃ (B)+TiO₂ (C)+Cr₂O₃ (D)

substrate+TiO₂ (A)+B₂O₃ (B)+TiO₂ (C)+Ce₂O₃ (D)

substrate+TiO₂ (A)+B₂O₃ (B)+TiO₂ (C)+V₂O₅ (D)

substrate+TiO₂ (A)+B₂O₃ (B)+TiO₂ (C)+MnO₂ (D)

substrate+TiO₂ (A)+B₂O₃ (B)+TiO₂ (C)+CoO (D)

substrate+TiO₂ (A)+B₂O₃ (B)+TiO₂ (C)+Ag₂O (D)

The pigments according to the invention can be prepared according to methods known in the art by the production of high- and low-refractive-index interference layers having precisely defined thickness and a smooth surface on the finely divided, flake-form substrates.

The metal-oxide layers are preferably applied by wet-chemical methods, it being possible to use the wet-chemical coating methods developed for the preparation of pearlescent pigments. Methods of this type are described, for example, in DE 14 67 468, DE19 59 988, DE20 09 566, DE22 14 545, DE22 15 191, DE22 44 298, DE23 13 331, DE25 22 572, DE31 37 808, DE31 37 809, DE31 51 343, DE3151354, DE31 51 355, DE 32 11 602, DE 32 35 017 or in further patent documents and other publications known to the person skilled in the art.

In the wet coating, the substrate particles are suspended in water, and one or more hydrolyzable metal salts are added at a pH which is suitable for hydrolysis and which is selected so that the metal oxides or metal oxide hydrates are precipitated directly onto the flakes without secondary precipitations occurring. The pH is usually kept constant by simultaneous metered addition of a base or acid. The pigments are subsequently separated off, washed and dried and, if desired, calcined, where the calcination temperature can be optimized with respect to the coating present in each case. In general, the calcination temperatures are between 250 and 1000° C., preferably between 350 and 900° C. If desired, the pigments can be separated off after application of individual coatings, dried and, if desired, calcined and then re-suspended for the deposition of the further layers.

The coating may furthermore also take place in a fluidized-bed reactor by gas-phase coating, it being possible, for example, to use correspondingly the methods proposed in EP 0 045 851 and EP 0 106 235 for the preparation of pearlescent pigments.

The production of Ti suboxide or Fe₃O₄ layers can be carried out, for example, by reduction of a TiO₂ or Fe₂O₃ layer using ammonia, hydrogen and also hydrocarbons and hydrocarbon/ammonia mixtures, as described, for example, in EP-A-0 332 071, DE 199 51 696 A1 and DE 199 51 697 A1. The reduction is preferably carried out in a forming-gas atmosphere (92% of N₂/8% of H₂ or 96% of N₂/4% of H₂). The reduction is generally carried out at temperatures of 250-1000° C., preferably 350-900° C. and in particular 500-850° C.

The hue of the pigments can be varied within broad limits through a different choice of the coating amounts or the layers resulting therefrom. Fine tuning for a certain hue can be achieved beyond the pure choice of amount by approaching the desired color under visual or measurement technology control.

In order to increase the light, water and weather stability, it is frequently advisable, depending on the area of application, to subject the finished pigment to post-coating or post-treatment. Suitable post-coatings or post-treatments are, for example, the processes described in German Patent 22 15 191, DE-A 31 51 354, DE-A 32 35 017, DE-A 33 34 598, DE 40 30 727 A1, EP 0 649 886 A2, WO 97/29059, WO 99/57204 and U.S. Pat. No. 5,759,255. This post-coating (layer E) further increases the chemical stability of the pigments or simplifies the handling of the pigment, in particular the incorporation into various media. In order to improve the wettability, dispersibility and/or compatibility with the application media, it is possible for functional coatings of Al₂O₃ or ZrO₂ or mixtures thereof or mixed phases to be applied to the pigment surface. Furthermore, organic or combined organic/inorganic post-coatings are possible, for example with silanes, as described, for example, in EP 0090259, EP 0 634 459, WO 99/57204, WO 96/32446, WO 99/57204, U.S. Pat. No. 5,759,255, U.S. Pat. No. 5,571,851, WO 01/92425 or in J. J. Ponjeé, Philips Technical Review, Vol. 44, No. 3, 81 ff. and P. H. Harding J. C. Berg, J. Adhesion Sci. Technol., Vol. 11 No. 4, pp. 471-493.

The pigments according to the invention are compatible with a multiplicity of color systems, preferably from the area of paints, coatings and printing inks. For the preparation of printing inks, a multiplicity of binders, in particular water-soluble grades, as marketed, for example, by BASF, Marabu, Proll, Sericol, Hartmann, Gebr. Schmidt, Sicpa, Aarberg, Siegberg, GSB-Wahl, Follmann, Ruco or Coates Screen INKS GmbH, is suitable. The printing inks can be water-based or solvent-based. The pigments are furthermore also suitable for the laser marking of paper and plastics and for applications in the agricultural sector, for example for greenhouse sheeting, and, for example, for the coloring of tent awnings.

It goes without saying that, for the various applications, the multilayered pigments can also advantageously be used in blends with organic dyes, organic pigments or other pigments, such as, for example, transparent and opaque white, colored and black pigments, and with flake-form iron oxides, organic pigments, holographic pigments, LCPs (liquid crystal polymers) and conventional transparent, colored and black lustre pigments based on metal oxide-coated mica and Sio₂ flakes, etc. The multilayered pigments can be mixed in any ratio with commercially available pigments and fillers.

The pigments according to the invention are furthermore suitable for the preparation of flowable pigment compositions and dry preparations, for example, by known methods. The pigment compositions and dry preparations are distinguished by the fact that they comprise one or more pigments according to the invention, binders and optionally one or more additives.

The invention thus also relates to the use of the pigments in formulations, such as paints, printing inks, coatings, plastics, ceramic materials, glasses, in cosmetic formulations, for laser marking and for the preparation of pigment compositions and dry preparations.

The following examples are intended to explain the invention in greater detail, but without restricting it.

The entire disclosure of all applications, patents and publications, cited herein and of corresponding German Application No. 10310736, filed Mar. 10, 2003, is incorporated by reference herein.

### EXAMPLES

Without further elaboration, it is believed that one skilled in the art can, using the preceding description, utilize the present invention to its fullest extent. The following preferred specific embodiments are, therefore, to be construed as merely illustrative, and not limitative of the remainder of the disclosure in any way whatsoever.

In the foregoing and in the following examples, all temperatures are set forth uncorrected in degrees Celsius and, all parts and percentages are by weight, unless otherwise indicated.

### Example 1

Step 1.1

100 g of mica having a particle size of 10-60 μm are suspended in 1.91 of deionized water and heated to 75° C. with vigorous stirring. 750 ml of TiCl₄ solution (400 g of TiCl₄/l) are metered into this suspension at pH=2.2. The pH is then adjusted to 7.5 using sodium hydroxide solution (32%), and 290 ml of sodium water-glass solution (13.5% of SiO₂) are metered in at this pH. During this addition, the pH is kept constant using hydrochloric acid (18%). 750 ml of TiCl₄ solution (400 g of TiCl₄/l) are subsequently metered in at pH 2.2. During the addition of the TiCl₄ solution, the pH is in each case kept constant using NaOH solution (32%).

For work-up, the green interference pigment is filtered off, washed with deionized water, dried at 110° C. and calcined at 800° C. for 30 minutes.

Step 1.2 (Coating with Fe₃O₄)

100 g of green interference pigment from step 1.1 are suspended in 1.91 of deionized water and heated to 80° C. with stirring. The pH of the pigment suspension is adjusted to pH 2.8 using 10% hydrochloric acid. 51 g of iron(III) chloride solution (15% solution) are subsequently metered in, during which the pH is kept constant using 32% sodium hydroxide solution. The suspension is subsequently stirred for 15 minutes. For work-up, the pigment is filtered off, washed with deionized water, dried at 110° C. and reduced at 575° C. for 30 minutes in a forming-gas atmosphere (92% of N₂/8% of H₂ or 96% of N₂/4% of H₂).

This gives a green pigment having the following Lab values (measured using a Minolta CR-300 calorimeter):

| | |
|---|---|
| L value: | 62 ± 1 |
| a value: | −17 ± 1 |
| b value: | 20 ± 2 |
| C value (chroma) | 27 ± 2 |
| h° value (hue angle): | 131 ± 1 |

### Example 2

Step 2.1

100 g of mica having a particle size of 10-60 μm are suspended in 1.91 of deionized water and heated to 75° C. with vigorous stirring. 420 ml of TiCl₄ solution (400 g of TiCl₄/l) are metered into this suspension at pH=2.2. The pH is then adjusted to 7.5 using sodium hydroxide solution (32%), and 212 ml of sodium water-glass solution (13.5% of SiO₂) are metered in at this pH. During this addition, the pH is kept constant using hydrochloric acid (18%). 420 ml of TiCl₄ solution (400 g of TiCl₄/l) are subsequently metered in at pH 2.2. During the addition of the TiCl₄ solution, the pH is in each case kept constant using NaOH solution (32%).

For work-up, the gold interference pigment is filtered off, washed with deionized water, dried at 110° C. and calcined at 800° C. for 30 minutes.

Step 2.2

100 g of mica having a particle size of 5-20 μm are suspended in 1.91 of deionized water and heated to 75° C. with vigorous stirring. About 800 ml of TiCl₄ solution (400 g of TiCl₄/l) are metered into this suspension at pH=2.0. The pH is then adjusted to pH 7 using sodium hydroxide solution (32%), and the mixture is stirred for about a further 30 minutes.

For work-up, the gold interference pigment is filtered off, washed with deionized water, dried at 110° C. and calcined at 800° C. for 30 minutes.

Step 2.3

A mixture of 100 g of coated mica pigment from step 2.1 and 100 g of coated mica pigment from step 2.2 is heated to 80° C. in 3800 ml of deionized water containing 200 g of NaCl. When the reaction temperature has been reached, the pH is adjusted to 2.8 by dropwise addition of hydrochloric acid (w=10%).

An FeCl₃ solution (28 g of 15% FeCl₃ solution and 56 g of H₂0) is subsequently metered in, during which the pH is kept constant at pH=2.8 using 32% sodium hydroxide solution. The mixture is subsequently stirred at 80° C. for 0.5 hour, and the pH is then adjusted to pH=7.0 using 32% sodium hydroxide solution. The mixture is stirred for a further 0.5 hour, the yellow pigment is filtered off, washed with water until salt-free and dried at 110° C. for 12 hours, and the pigment is sieved (mesh width 0.3 mm). Finally, the pigment is calcined at 800° C.

This gives a gold-colored pigment having the following Lab values (measured using a Minolta CR-300 calorimeter):

| | |
|---|---|
| L value: | 82 ± 1 |
| a value: | 4 ± 1 |
| b value: | 38 ± 2 |
| C value (chroma) | 38 ± 2 |
| h° value (hue angle): | 85 ± 1 |

### Example 3

Step 3.1

100 g of mica having a particle size of 10-60 μm are suspended in 1.91 of deionized water and heated to 75° C. with vigorous stirring. 676 ml of TiCl₄ solution (400 g of TiCl₄/l) are metered into this suspension at pH=2.2. The pH is then adjusted to 7.5 using sodium hydroxide solution (32%), and 209 ml of sodium water-glass solution (13.5% of SiO₂) are metered in at this pH. During this addition, the pH is kept constant using hydrochloric acid (18%). 676 ml of TiCl₄ solution (400 g of TiCl₄/l) are subsequently metered in at pH 2.2. During the addition of the TiCl₄ solution, the pH is in each case kept constant using NaOH solution (32%).

For work-up, the blue interference pigment is filtered off, washed with deionized water, dried at 110° C. and calcined at 800° C. for 30 minutes.

Step 3.2 (Coating with Fe₃O₄)

100 g of blue interference pigment from step 3.1 are suspended in 1.91 of deionized water and heated to 80° C. with stirring. The pH of the pigment suspension is adjusted to pH 2.8 using 10% hydrochloric acid. 47 g of iron(III) chloride solution (15% solution) are subsequently metered in, during which the pH is kept constant using 32% sodium hydroxide solution. The suspension is subsequently stirred for 15 minutes. For work-up, the pigment is filtered off, washed with deionized water, dried at 110° C. and reduced at 575° C. for 30 minutes in a forming-gas atmosphere (92% of N₂/8% of H₂ or 96% of N₂/4% of H₂).

This gives a blue pigment having the following Lab values (measured using a Minolta CR-300 colorimeter):

| | |
|---|---|
| L value: | 49 ± 1 |
| a value: | 1.2 ± 1 |
| b value: | −20 ± 2 |
| C value (chroma) | 20 ± 2 |
| h° value (hue angle): | 273 ± 1 |

### Example 4

Step 4.1

130 g of mica having a particle size of 10-60 μm are suspended in 2.51 of deionized water and heated to 75° C. with vigorous stirring. 879 ml of TiCl₄ solution (400 g of TiCl₄/l) are metered into this suspension at pH=2.2. The pH is then adjusted to 7.5 using sodium hydroxide solution (32%), and 272 ml of sodium water-glass solution (13.5% of SiO₂) are metered in at this pH. During this addition, the pH is kept constant using hydrochloric acid (18%). 879 ml of TiCl₄ solution (400 g of TiCl₄/l) are subsequently metered in at pH 2.2. During the addition of the TiCl₄ solution, the pH is in each case kept constant using NaOH solution (32%).

The pH of the pigment suspension is adjusted to pH 2.8 using 32% sodium hydroxide solution. 80 g of iron(III) chloride solution are subsequently metered in, during which the pH is kept constant using 32% sodium hydroxide solution. The suspension is subsequently stirred for 15 minutes. The pH is subsequently adjusted from 2.8 to pH 5.0 using 32% sodium hydroxide solution. For work-up, the pigment is filtered off, washed with deionized water and dried at 110° C.

Step 4.1.1

The dried pigment is reduced at 575° C. for 30 minutes in a forming-gas atmosphere (92% of N₂/8% of H₂ or 96% of N₂/4% of H₂).

This gives a blue pigment having the following Lab values (measured using a Minolta CR-300 colorimeter):

| | |
|---|---|
| L value: | 55 ± 1 |
| a value: | −2 ± 1 |
| b value: | −22 ± 2 |
| C value (chroma) | 22 ± 2 |
| h° value (hue angle): | 265 ± 1 |

Step 4.1.2

The dried pigment is calcined at 800° C. for 30 minutes and then reduced at 575° C. for 30 minutes in a forming-gas atmosphere (92% of N₂/8% of H₂ or 96% of N₂/4% of H₂).

This gives a high-chroma, blue pigment having the following Lab values (measured using a Minolta CR-300 colorimeter):

| | |
|---|---|
| L value: | 52 ± 1 |
| a value: | 0.6 ± 1 |
| b value: | −27 ± 2 |
| C value (chroma) | 27 ± 2 |
| h° value (hue angle): | 271 ± 1 |

### USE EXAMPLES

### Example A

### Nail Varnish

| | |
|---|---|
| 2.00% | of pigment from Example 3 |
| 98.00% | of thixotropic nail varnish base 1348 |
| | (toluene, ethyl acetate, butyl acetate, |
| | nitrocellulose, tosylamide/formaldehyde resin, |
| | dibutyl phthalate, isopropyl |
| | alcohol, stearalkonium hectorite, |
| | camphor, acrylate copolymer, |
| | benzophenone-1 (2)) |

Sources of Supply:

(1) Merck KGaA

(2) International Lacquers S.A.

### Example B

### Eye Shadow

Phase A

| | |
|---|---|
| 30.00% | of pigment from Example 3 |
| 49.50% | of talc (1) |
| 7.50% | of potato starch (solanum tuberosum) (2) |
| 2.50% | of magnesium stearate (1) |

Phase B

| | |
|---|---|
| 9.14% | of isopropyl stearate (3) |
| 0.53% | of cetyl palmitate (1) |
| 0.53% | of Ewalin 1751 (petrolatum) (4) |
| 0.20% | of fragrance Elegance # 79228 D MF (perfume) (5) |
| 0.10% | of propyl-4-hydroxybenzoate (propylparaben) (1) |

The constituents of phase A are mixed homogeneously. The molten phase B is subsequently added with stirring to the powder mixture. The powders are pressed at 40-50 bar.

Sources of Supply:

(1) Merck KGaA

(2) Suidstarke GmbH

(3) Cognis GmbH

(4) H. Erhard Wagner GmbH

(5) Haarmann & Reimer GmbH

### Example C

### Lipstick

Phase A

| | |
|---|---|
| 15.00% | of pigment from Example 1 |

Phase B

| | |
|---|---|
| 8.75% | of beeswax white (cera alba) (1) |
| 5.25% | of Paracera C 44 (copernicia cerifera |
| | (carnauba wax, ceresin) (2) |
| 3.50% | of adeps lanae (lanolin) (3) |
| 5.60% | of isopropyl myristate (4) |
| 2.10% | of paraffin viscous |
| | (paraffinum liquidum (mineral oil) (1) |
| 0.05% | of OXYNEX ® K liquid (PEG-8, |
| | tocopherol, ascorbyl palmitate, ascorbic |
| | acid, citric acid) (1) |
| 0.10% | of propyl 4-hydroxybenzoate (propylparaben) (1) |
| 59.45% | of castor oil (ricinus communis) (3) |

Phase C

| | |
|---|---|
| 0.20% | of fragrance Tendresse # 75418C (perfume) (5) |

The constituents of phase B are heated to 75° C. and melted. The pigments of phase A are added, and everything is stirred well. The lipstick composition is then stirred for 15 minutes with the perfume from phase C in the casting apparatus heated to 65° C. The homogeneous melt is poured into the casting moulds pre-warmed to 55° C. The moulds are subsequently cooled, and the castings are removed cold.

Sources of Supply:

(1) Merck KGaA

(2) Paramelt

(3) Henry Lamotte GmbH

(4) Cognis GmbH

(5) Haarmann & Reimer GmbH

### Example D

### Clear Shower Gel

Phase AL

| | |
|---|---|
| 0.10% | of pigment from Example 1 |
| 0.75% | of Keltrol T (xanthan gum) (2) |
| 65.15% | of water (aqua) |

Phase B

| | |
|---|---|
| 20.00% | of Plantacare 2000 UP (decyl glucoside) (3) |
| 3.60% | of Texapon ASV (magnesium oleth sulfate, sodium |
| | oleth sulfate, magnesium laureth-8 sulfate, |
| | sodium laureth-8 sulfate, magnesium laureth |
| | sulfate, sodium laureth sulfate (3) |
| 0.20% | of Brondidox L (propylene glycol, |
| | 5-bromo-5-nitro-1,3-dioxane (3) |
| 0.05% | of fragrance Everest 79658 SB (perfume) (4) |
| q.s. % | of dye stuff solution |

Phase C

| | |
|---|---|
| 0.15% | of citric acid monohydrate (citric acid) (1) |
| 10.00% | of water, demineralized (aqua) |

The pigment is dispersed in the water of phase A. Addition of Keltrol T and careful mixing of the constituents. Phase B and phase C are added to phase A with stirring. The mixture is stirred slowly until the homogeneous gel has formed. The pH is adjusted to 6.0-6.5.

Sources of Supply:

(1) Merck KGaA

(2) Kelco

(3) Cognis GmbH

(4) Haarmann & Reimer GmbH

### Example E

### Eye Shadow Gel

Phase A

| | |
|---|---|
| 17.00% | of pigment from Example 3 |
| 6.00% | of Ronasphere ® (silica) (1) |
| 72.00% | of water, demineralized (aqua) |

Phase B

| | |
|---|---|
| 2.00% | of Keltrol SF (xanthan gum) (1) |

Phase C

| | |
|---|---|
| 2.00% | of glycerol, anhydrous (glycerin) (1) |
| 1.00% | of Phenochem (phenoxyethanol, methylparaben, ethylparaben, |
| | propylparaben, butylparaben, isobutylparaben) (3) |

The constituents of phase A are mixed. Slow addition of phase B and stirring until a homogeneous solution is obtained. Dissolution of the constituents of phase C and stirring until a homogeneous solution has formed. Addition of phase C to phase A and B with stirring and adjustment of the pH to 6.0-7.0.

Sources of Supply:

(1) Merck KGaA/Rona®

(2) Kelco

(3) Sharon Labs

### Example F

### Mascara

Phase A

| | |
|---|---|
| 15.00% | of pigment from Example 3 |

Phase

| | |
|---|---|
| 8.00% | of stearic acid (stearic acid) (1) |
| 6.00% | of beeswax white (cera alba) (1) |
| 4.00% | of carnauba wax 2442 L (copernicia cerifera) (2) |
| 3.00% | of Eutanol G (octyldodecanol) (3) |
| 2.00% | of Arlacel 83 (sorbitan sesquioleate) (4) |
| 0.10% | of propyl 4-hydroxybenzoate (propylparaben) (1) |
| 0.50% | of RonaCare ™ tocopherol acetate |
| | (tocopheryl acetate) (1) |

Phase C

| | |
|---|---|
| 2.30% | of triethanolamine (1) |
| 8.00% | of water soluble shellac SSB 63 (shellac) (5) |
| 0.25% | of methyl 4-hydroxybenzoate (methylparaben) (1) |
| 0.01% | of RonaCare ™ biotin (biotin) (1) |
| 50.84% | of water, demineralized (aqua) |

The constituents of phase B are heated to 80° C. and melted with stirring. Shellac from phase C is mixed with water, heated to 75° C. and dissolved in the other constituents of phase C. Phase C is added to the mixture of phase A and phase B at 75° C. and homogenized for 2 minutes. The mascara is cooled to room temperature and adjusted to pH 7.0-7.5.

Sources of Supply:

(1) Merck KGaA/Rona®

(2) Kahl & Co.

(3) Cognis GmbH

(4) Uniqema

(5) Paroxite Ltd.

### Example G

### Plastic

In each case,

a) 1% of pigment From Example 1

b) 1% of pigment From Example 2

c) 1% of pigment From Example 3

d) 1% of pigment From Example 3 and 0.1% of PV True Blue B2G01 (Pigment Blue 15,3)

are added to the plastic granules polypropylene PP Stamylan PPH10 (DSM) or polystyrene 143E (BASF).

The pigmented granules are subsequently converted into stepped plates in an injection-molding machine. On use of the pigments according to the invention, a colored plastic having an intense color is obtained.

### Example H

### Printing Ink

The pigment was stirred into the solvent-containing binder at 600 rpm, and the printing inks were subsequently applied to black/white cards using a hand coater.

Ink No. 1:

| | |
|---|---|
| 88.0 g | of Gebr. Schmidt 95 MB 011 TW |
| 10.0 g | of pigment from Example 4 |
| 2.0 g | of Gebr. Schmidt 95 MB 022-TW (green) |

Ink No. 2:

| | |
|---|---|
| 88.0 g | of Gebr. Schmidt 95 MB 011 TW |
| 10.0 g | of pigment from Example 1 |
| 2.0 g | of Gebr. Schmidt 95 MB 022-TW (green) |

### Example I

### Automotive Paint

| | |
|---|---|
| 2.00 g | of pigment from Example 3 |
| 1.50 g | of Heliogen Blue L 6930 |
| 0.20 g | of Hostaperm Green 8G |
| 0.05 g | of pigment-grade carbon black FW 200 |
| 66.60 g | of paint base (A4) MP system (solids content = 19%) |
| 29.65 g | of diluent mixture |

The preceding examples can be repeated with similar success by substituting the generically or specifically described reactants and/or operating conditions of this invention for those used in the preceding examples.

From the foregoing description, one skilled in the art can easily ascertain the essential characteristics of this invention and, without departing from the spirit and scope thereof, can make various changes and modifications of the invention to adapt it to various usages and conditions.

1. An interference pigment having a mass tone, which comprises a flake-form substrate with successive coatings of:
(A) a colorless coating having a refractive index of n>1.8 in a layer thickness of 20-250 nm,
(B) a colorless coating having a refractive index of n≦1.8 in a layer thickness of 10-100 nm,
(C) a colorless coating having a refractive index of n>1.8 in a layer thickness of 20-250 nm,
(D) an absorbent layer having a layer thickness of 1-100 nm, and, optionally,
(E) an outer protective layer.

2. An interference pigment according to claim 1, wherein the flake-form substrate is natural or synthetic mica, glass flake, Al₂O₃ flake, SiO₂ flake or TiO₂ flake, or a mixture thereof.

3. An interference pigment according to claim 1, wherein coating (A) consists of TiO₂, ZrO₂, ZnO or BiOCl.

4. An interference pigment according to claim 2, wherein coating (A) consists of TiO₂, ZrO₂, ZnO or BiOCl.

5. An interference pigment according to claim 1, wherein coating (B) consists of SiO₂, MgF₂, B₂O₃, AlO(OH), MgSiO₃ or Al₂O₃, or mixtures thereof.

6. An interference pigment according to claim 2, wherein coating (B) consists of SiO₂, MgF₂, B₂O₃, AlO(OH), MgSiO₃ or Al₂O₃, or mixtures thereof.

7. An interference pigment according to claim 3, wherein coating (B) consists of SiO₂, MgF₂, B₂O₃, AlO(OH), MgSiO₃ or Al₂O₃, or mixtures thereof.

8. An interference pigment according to claim 1, wherein the absorbent layer (D) is selected from metal oxides, sulfides, tellurides, selenides, lanthanides, phosphates, actinides and mixtures thereof.

9. An interference pigment according to claim 1, wherein the absorbent layer (D) consists of Fe₂O₃, Fe₃O₄, Cr₂O₃, Ce₂O₃, Cr₂O₃, a molybdenum oxide, CoO, Co₃O₄, VO₂, V₂O₃, NiO, V₂O₅, CuO, Cu₂O, Ag₂O, CeO₂, MnO₂, Mn₂O₃, Mn₂O₅, MoS₂, WS₂, a titanium oxynitride, titanium nitride or any combination of the above.

10. An interference pigment according to claim 2, wherein the absorbent layer (D) consists of Fe₂O₃, Fe₃O₄, Cr₂O₃, Ce₂O₃, Cr₂O₃, a molybdenum oxide, CoO, Co₃O₄, VO₂, V₂O₃, NiO, V₂O₅, CuO, Cu₂O, Ag₂O, CeO₂, MnO₂, Mn₂O₃, Mn₂O₅, Mos₂, WS₂, a titanium oxynitride, titanium nitride or any combination of the above.

11. An interference pigment according to claim 3, wherein the absorbent layer (D) consists of Fe₂O₃, Fe₃0₄, Cr₂O₃, Ce₂O₃, Cr₂O₃, a molybdenum oxide, CoO, Co₃O₄, VO₂, V₂O₃, NiO, V₂O₅, CuO, Cu₂O, Ag₂O, CeO₂, MnO₂, Mn₂O₃, Mn₂O₅, MoS₂, WS₂, a titanium oxynitride, titanium nitride or any combination of the above.

12. An interference pigment according to claim 5, wherein the absorbent layer (D) consists of Fe₂O₃, Fe₃0₄, Cr₂O₃, Ce₂O₃, Cr₂O₃, a molybdenum oxide, CoO, Co₃O₄, VO₂, V₂O₃, NiO, V₂O₅, CuO, Cu₂O, Ag₂O, CeO₂, MnO₂, Mn₂O₃, Mn₂O₅, Mos₂, WS₂, a titanium oxynitride, titanium nitride or any combination of the above.

13. An interference pigment according to claim 1, wherein coating (A) and coating (C) have the same composition.

14. An interference pigment according to claim 3, wherein coating (A) and coating (C) have the same composition.

15. An interference pigment according to claim 13, wherein coating (A) and coating (C) consist of TiO₂.

16. A process for producing an interference pigment according to claim 1, which comprises coating the flake-form substrate by a wet-chemical method of hydrolytic decomposition of metal salts in aqueous medium or by a CVD or PVD process.

17. A paint, coating, printing ink, plastic, ceramic, glass, cosmetic, or laser markable composition comprising a pigment of claim 1.

18. A pigment composition comprising one or more binders, optionally one or more additives, and one or more interference pigments according to claim 1.

19. A dry preparation comprising an interference pigment according to claim 1.

20. A dry preparation of claim 19, in the form of pellets, granules, chips or briquettes.
